(19) United States
(12) Patent Application Publication
(10) Pub. No.: US 2024/0429162 A1
(43) Pub. Date: Dec. 26, 2024

(54) INTEGRATED CIRCUIT DEVICES WITH CONDUCTIVE LINES EXTENDING OVER SCRIBE LINES

(71) Applicant: Intel Corporation, Santa Clara, CA (US)

(72) Inventors: Abhishek A. Sharma, Portland, OR (US); Tahir Ghani, Portland, OR (US); Sagar Suthram, Portland, OR (US); Anand S. Murthy, Portland, OR (US); Wilfred Gomes, Portland, OR (US)

(73) Assignee: Intel Corporation, Santa Clara, CA (US)

(21) Appl. No.: 18/340,072

(22) Filed: Jun. 23, 2023

(51) Int. Cl. H01L 23/528

(52) U.S. Cl. CPC H01L 23/528; H01L 23/49833; H01L 24/16; H01L 25/0655; H01L 2224/16227

(57) ABSTRACT

An example IC device includes a substrate comprising a plurality of areas and one or more scribe lines defining boundaries of individual areas of the plurality of areas. The plurality of areas includes a first area and a second area. The IC device further includes a scribe line between the first area and the second area, a first device layer over the first area of the substrate and a first metallization stack over the first device layer, a second device layer over the second area of the substrate and a second metallization stack over the second device layer, and a conductive line extending (e.g., being materially and electrically continuous) between the first metallization stack and the second metallization stack, where a projection of the conductive line onto a plane parallel to the substrate and containing the scribe line intersects the scribe line.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### BRIEF DESCRIPTION OF THE DRAWINGS

Embodiments will be readily understood by the following detailed description in conjunction with the accompanying drawings.

FIG. 1 provides a block diagram of an integrated circuit (IC) device that may include one or more conductive lines extending over one or more scribe lines, according to some embodiments of the present disclosure.

FIG. 2 provides top views of a wafer, a die, and an IC device with conductive lines extending over scribe lines, according to some embodiments of the present disclosure.

FIG. 3 provides a top view of a wafer based on which an IC device with conductive lines extending over scribe lines may be implemented, according to some embodiments of the present disclosure.

FIG. 4 illustrates a cross-sectional side view of an example IC device with a conductive line extending over a scribe line, according to some embodiments of the present disclosure.

FIG. 5 is a cross-sectional side view of an IC package that may include an IC device with one or more conductive lines extending over one or more scribe lines in accordance with any of the embodiments disclosed herein.

FIG. 6 is a cross-sectional side view of an IC device assembly that may include an IC device with one or more conductive lines extending over one or more scribe lines in accordance with any of the embodiments disclosed herein.

FIG. 7 is a block diagram of an example computing device that may include an IC device with one or more conductive lines extending over one or more scribe lines in accordance with any of the embodiments disclosed herein.

FIG. 8 is a block diagram of an example processing device that may include an IC device with one or more conductive lines extending over one or more scribe lines in accordance with any of the embodiments disclosed herein.

### DETAILED DESCRIPTION

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

IC fabrication usually includes two stages. The first stage is referred to as the front-end of line (FEOL). The second stage is referred to as the back-end of line (BEOL). In the FEOL, individual IC components (e.g., transistor, capacitors, resistors, etc.) can be patterned in a wafer. In the BEOL, interconnect structures such as conductive lines and conductive vias, separated as needed by an insulator material, can be formed to get the individual components interconnected. The BEOL usually starts with forming the first metal layer on the wafer. The first metal layer is often called M0. More metal layers can be formed on top of M0, and these metal layers are often called M1, M2, and so on. Together, a plurality of layers in the BEOL are referred to as a “metallization stack” of an IC device. In this context, the term “metal layer” refers to a layer, formed over a wafer, that includes electrically conductive interconnect structures (e.g., conductive lines and conductive vias) for providing electrical connectivity between different IC components (e.g., those of the FEOL layer). Metal layers described herein may also be referred to as “interconnect layers” to clearly indicate that these layers include electrically conductive interconnect structures which may, but does not have to, be metal. Generally speaking, each of the metal layers of a metallization stack may include a conductive line (also sometimes referred to as a “trench,” a “trace,” or a “metal line”) and/or a conductive via. Conductive lines of a metal layer are configured for transferring signals and power along electrically conductive (e.g., metal) structures extending in the x-y plane (e.g., in the x or y directions), while the conductive vias of a metal layer are configured for transferring signals and power through electrically conductive structures extending in the z-direction, e.g., to any of the adjacent metal layers above or below. Accordingly, conductive vias connect interconnect structures (e.g., conductive lines and/or conductive vias) of one metal layer to interconnect structures of an adjacent metal layer.

Electron-beam (e-beam) lithography may be used to pattern conductive lines in different layers of a metallization stack. As known in the art, e-beam lithography starts with using an e-beam lithography tool to scan a focused beam of electrons to draw custom shapes on a surface covered with an electron-sensitive film called a “resist” (exposing). The electron beam changes the solubility of the resist, enabling selective removal of either the exposed or non-exposed regions of the resist by immersing it in a solvent (developing). As with photolithography where a light beam is used for exposing, the purpose of e-beam lithography is to create very small structures in the resist that can subsequently be transferred to the desired material, often by etching.

One advantage of e-beam lithography is that it can draw custom patterns (direct-write) with resolution below as little as 10 nanometers. However, e-beam lithography is typically a localized process, carried out on surface areas that are maximum about 500 by 500 micron. This has implications on using e-beam lithography for forming conductive lines of metallization stacks on a wafer. In particular, a wafer contains multiple dies, with scribe lines defining boundaries between the dies. A scribe line is a space on a wafer between the dies, the space being large enough to subsequently allow separation of the dies by cutting or breaking (a process called “singulation”) without damaging the dies. When individual IC components such as transistors, capacitors, and resistors, are fabricated on a wafer as a part of FEOL processing, they are formed on individual dies, and the scribe lines remain free of such IC components. When e-beam lithography is used for forming conductive lines of metallization stacks on a wafer as a part of BEOL processing, e-beam lithography is localized to forming conductive lines within individual dies. Thus, in conventional semiconductor processing, areas of metallization stacks above the scribe lines are free of conductive lines (as well as of conductive vias).

Embodiments of the present disclosure are based on recognition that it may be desirable to have conductive lines above the wafer that extend across multiple dies, over the scribe lines. One example where this may be desired is if multiple dies of a wafer are not to be separated from one another later on but to remain together in a final IC device is for high-performance computing (HPC) applications. Embodiments of the present disclosure are further based on recognition that using multiple e-beam lithography scanners in tight proximity to one another (a technique called “multi-beam e-beam lithography”) may be used to scan focused beams of electrons over larger areas, including areas of two or more dies, thus patterning conductive lines that extend across two or more adjacent dies and over the scribe lines between them. An example IC device includes a substrate comprising a plurality of areas and one or more scribe lines defining boundaries of individual areas of the plurality of areas. The plurality of areas includes a first area and a second area. The IC device further includes a scribe line between the first area and the second area, a first device layer over the first area of the substrate and a first metallization stack over the first device layer, a second device layer over the second area of the substrate and a second metallization stack over the second device layer, and a conductive line extending (e.g., being materially and electrically continuous) between the first metallization stack and the second metallization stack, over the scribe line (e.g., a projection of the conductive line onto a plane parallel to the substrate and containing the scribe line intersects the scribe line).

Various IC devices with one or more conductive lines extending over one or more scribe lines as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. Although certain elements may be referred to in the singular herein, such elements may include multiple sub-elements. For example, “an insulator material” may include one or more insulator materials. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. For example, the term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. With reference to optical signals and/or devices, components and elements that operate on or using optical signals, the term “conducting” can also mean “optically conducting.”

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

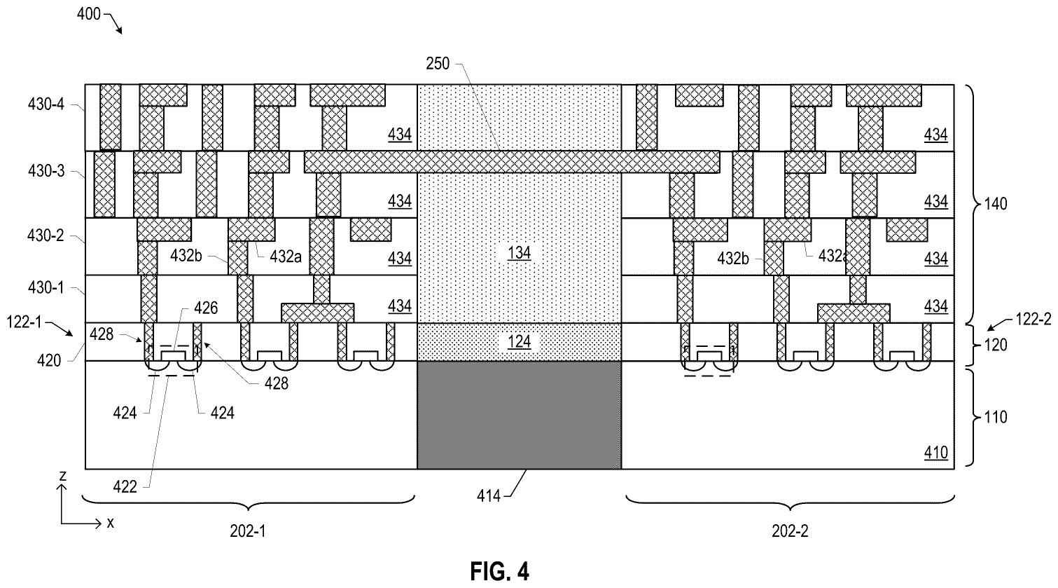

Any of the features discussed with reference to any of accompanying drawings herein may be combined with any other features to form IC devices with one or more conductive lines extending over one or more scribe lines, as appropriate. A number of elements of the drawings are shared with others of the drawings; for ease of discussion, a description of these elements is not repeated, and these elements may take the form of any of the embodiments disclosed herein. If multiple instances of certain elements are illustrated, then, in some cases, to not clutter the drawings only some of these elements may be labeled with a reference sign and other ones of these elements are not labeled (e.g., although FIG. 4 illustrates six transistors 422, only one of them is labeled with a reference sign). However, in other cases, for ease of explanation, different instances of a given element in a single drawing may be referred to with numbers 1, 2, and so on, after a dash (e.g., FIG. 4 illustrates multiple metal layers 430, labeled individually as metal layers 430-1, 430-2, 430-3, and 430-4).

The drawings are not necessarily to scale. Although many of the drawings illustrate rectilinear structures with flat walls and right-angle corners, this is simply for ease of illustration and may not reflect real-life process limitations which may cause various features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used to describe a range of dimensions, the phrase “between X and Y” represents a range that includes X and Y. When used to describe a location of an element, the phrase “between X and Y” represents a region that is spatially between element X and element Y. The description may use the phrases “in an embodiment” or “in embodiments,” which may each refer to one or more of the same or different embodiments. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2%, of a target value based on the context of a particular value as described herein or as known in the art.

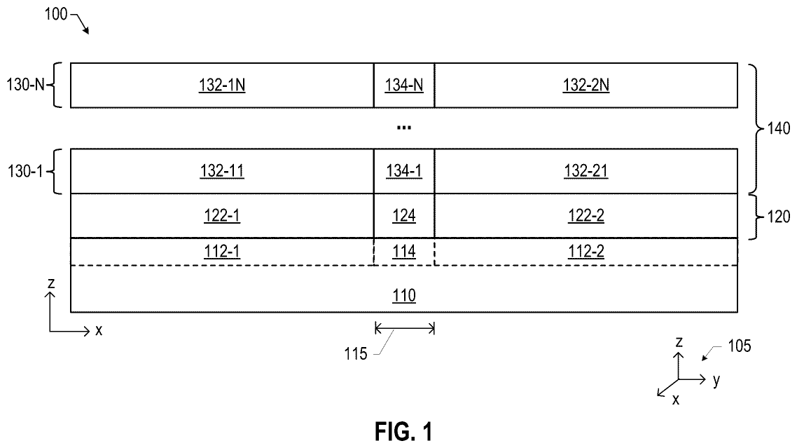

FIG. 1 illustrates a cross-sectional view of an example IC device 100 that may include one or more conductive lines extending over one or more scribe lines, according to some embodiments of the present disclosure. FIG. 1 illustrates an example coordinate system 105 with axes x-y-z so that the various planes illustrated in FIG. 1 and in some subsequent drawings may be described with reference to this coordinate system.

As shown in FIG. 1, in general, the IC device 100 may include a support 110, a device layer 120, and a plurality of metal layers 130. The illustration of FIG. 1 is intended to provide a general orientation and arrangement of various layers/areas with respect to one another, and, unless specified otherwise in the present disclosure, includes embodiments of the IC device 100 where portions of elements described with respect to one of the layers shown in FIG. 1 may extend into one or more, or be present in, other layers. One example implementation of the IC device 100 is an IC device 400, shown in FIG. 4 and described below.

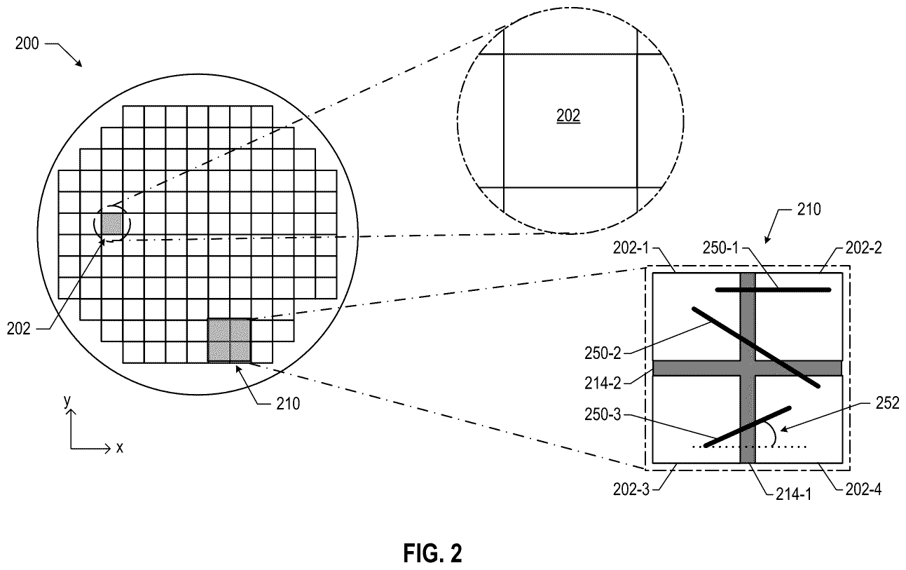

The support 110 may be any suitable support over which the device layer 120 may be provided. For example, the support 110 may be a substrate, a wafer or a chip. The support 110 may, e.g., be the wafer 200 of FIG. 2, discussed below. In particular, the support 110 of the IC device 100 may include a plurality of areas 112 and one or more scribe lines 114 defining the boundaries of the areas 112. Example shown in FIG. 1 illustrates two areas 112, individually labeled as a first area 112-1 and a second area 112-2, and one scribe line 114 between the areas 112-1 and 112-2. However, in other embodiments, the IC device 100 may include any number of two or more areas 112 and any number of one or more scribe lines 114. The areas 112 may be, or may correspond to, individual dies of a wafer, e.g., to dies 202 of the wafer 200 of FIG. 2. The scribe line 114 may be a scribe in between a pair of adjacent dies 202 of the wafer 200. Although FIG. 1 illustrates the areas 112 at the top of the support 110, in other embodiments the areas 112 may extend through the support 110. Similarly, although FIG. 1 illustrates the scribe line 114 at the top of the support 110, in other embodiments the scribe line 114 may extend through the support 110, be at the bottom of the support 110, be in the middle of the support 110, or in any other position along the z-axis suitable for defining the boundary between the areas 112. In some embodiments, a width 115 of the scribe line 114 (e.g., a dimension measured along the x-axis of the coordinate system 105) may be between about 50 micron and 200 micron. In some embodiments, a length of the scribe line 114 (e.g., a dimension measured along the y-axis of the coordinate system 105) may be at least about 1 millimeter.

In some embodiments, the support 110 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 110 may be a printed circuit board (PCB) substrate. Although a few examples of materials from which the substrate may be formed are described here, any material that may serve as a foundation upon which a semiconductor device with one or more conductive lines extending over one or more scribe lines as described herein may be built falls within the spirit and scope of the present disclosure.

The device layer 120 may include respective portions 122 over different areas 112. For example, as shown in FIG. 1, the device layer 120 may include a first portion 122-1 over the first area 112-1 and a second portion 122-2 over the second area 112-2. If the IC device 100 includes more than two areas 112, then it would also include the same number of portions 122 of the device layer 120, e.g., in a one-to-one correspondence. The device layer 120 may further include a portion 124 over the scribe line 114. Portions 122 of the device layer 120 may include any combination of active ICs, and any combination of IC components, provided over the support 110. For example, in some embodiments, the portions 122 of the device layer 120 may include various logic layers, circuits, and devices (e.g., logic circuits) to drive and control a logic IC. In some embodiments, the portions 122 of the device layer 120 may include memory devices/circuits. Later on, IC components of different ones of the portions 122 may be electrically connected to one another using conductive lines that extend over the scribe lines as described herein. In contrast, while the portion 124 of the device layer 120 may also include active IC components (e.g., transistors, capacitors, and/or memory devices/circuits) as such active IC components are sometimes included in and above the scribe line 114 to be used for metrology (e.g., for testing the dies as a part of wafer processing), none of the IC components of the scribe line 114 and the portion 124 are electrically connected to any components or interconnect structures in any of the portions 122. In some embodiments, the portion 124 may be void of any active ICs, e.g., it may be void of any transistors or/and memory devices/circuits.

As shown in FIG. 1, a plurality of metal layers 130 may include metal layers 130-1 through 130-N, where N is an integer equal to or greater than 1. The metal layers 130 may be, or include, metal layers of a BEOL. Together, the metal layers 130 may be referred to as a metallization stack 140 of the IC device 100. As used herein, the term “metal layer” may refer to a layer above a support 110 that includes electrically conductive interconnect structures (e.g., conductive lines and conductive vias) for providing electrical connectivity between different IC components. Metal layers described herein may also be referred to as “metal layers” to clearly indicate that these layers include electrically conductive interconnect structures which may, but does not have to, be metal. The metal layers 130 may be used to interconnect the various inputs and outputs of the active devices (e.g., transistors) in the device layer 120.

Similar to the device layer 120, each of the metal layers 130 may include respective portions 132 over different portions 122 of the device layer 120. For example, as shown in FIG. 1, the metal layer 130-1 may include a first portion 132-11 over the first portion 122-1 of the device layer 120 and a second portion 132-21 over the second portion 122-2 of the device layer 120, and so on, until the metal layer 130-N which may include a first portion 132-1N over the first portion 132-1 of the metal layer 130 underneath the metal layer 130-N and a second portion 132-2N over the second portion 132-1 of the metal layer 130 underneath the metal layer 130-N. Thus, in the notation of two digits provided after the dash in association with portions 132 of different metal layers 130, the first digit indicates a portion of a given metal layer 130, and the second digit identifies the metal layer 130 out of a plurality of metal layers 130 of the metallization stack 140. If the IC device 100 includes more than two areas 112, then it would also include the same number of portions 132 of each of the metal layers 130, e.g., in a one-to-one correspondence. Each metal layer 130 may further include a portion 134 over the scribe line 114.

Generally speaking, each portion 132 of the metal layers 130 may include a conductive line (also sometimes referred to as a “trench,” a “trace,” or a “metal line”) and/or a conductive via. Conductive lines of a metal layer are configured for transferring signals and power along electrically conductive (e.g., metal) structures extending in the x-y plane (e.g., in the x or y directions), while the conductive vias of a metal layer are configured for transferring signals and power through electrically conductive structures extending in the z-direction, e.g., to any of the adjacent metal layers above or below. Accordingly, conductive vias connect interconnect structures (e.g., conductive lines and/or conductive vias) of one metal layer to interconnect structures of an adjacent metal layer. While referred to as “metal” layers, various layers of the metal layers 130 may include only certain patterns of conductive metals, e.g., copper (Cu), aluminum (Al), tungsten (W), or cobalt (Co), or metal alloys, or more generally, patterns of an electrically conductive material, formed in an insulating medium such as an interlayer dielectric (ILD). The insulating medium may include any suitable ILD materials such as silicon oxide, carbon-doped silicon oxide, silicon carbide, silicon nitride, aluminum oxide, and/or silicon oxynitride. Furthermore, one or more of the metal layers 130 may further include a conductive line that extends through the portion 134 (i.e., over the scribe line 114) and electrically connects one or more of conductive lines and/or conductive vias of the metal layers 130-1 above the first area 112-1 with one or more of conductive lines and/or conductive vias of the metal layers 130-2 above the second area 112-2. Thus, conductive lines that extend through the portion 134 may be used to provide electrical connectivity between IC components (e.g., transistors, capacitors, and/or memory devices/circuits) and interconnect structures (e.g., conductive lines and/or conductive vias) associated with different areas 112 (e.g., associated with different dies 202, as described below). In contrast, while the portion 134 of the metallization stack 140 may also include interconnect structures (e.g., conductive lines and/or conductive vias) as such interconnect structures are sometimes included in and above the scribe line 114 to be used for metrology (e.g., for testing the dies as a part of wafer processing), none of the interconnect structures in the portion 134 (i.e., above the scribe line 114) are electrically connected to any components or interconnect structures in any of the portions 122 or any of the portions 132.

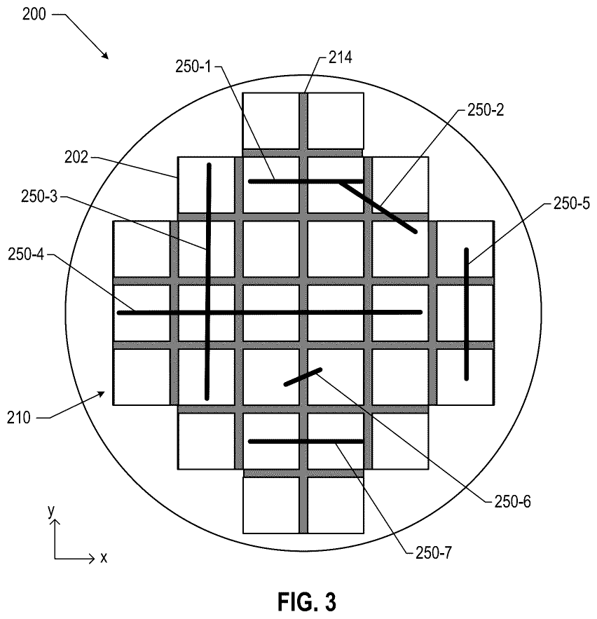

Some example implementations of having conductive lines extending over scribe lines are illustrated in top-down views of example wafers shown in FIG. 2 and FIG. 3. One example implementation of the IC device 100 is an IC device 400 shown in FIG. 4.

FIG. 2 provides top views of a wafer 200, a die 202, and an IC device 210 with conductive lines extending over scribe lines, according to some embodiments of the present disclosure.

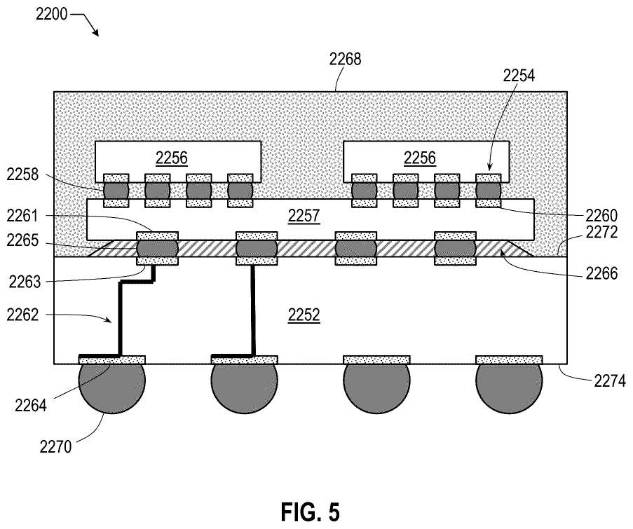

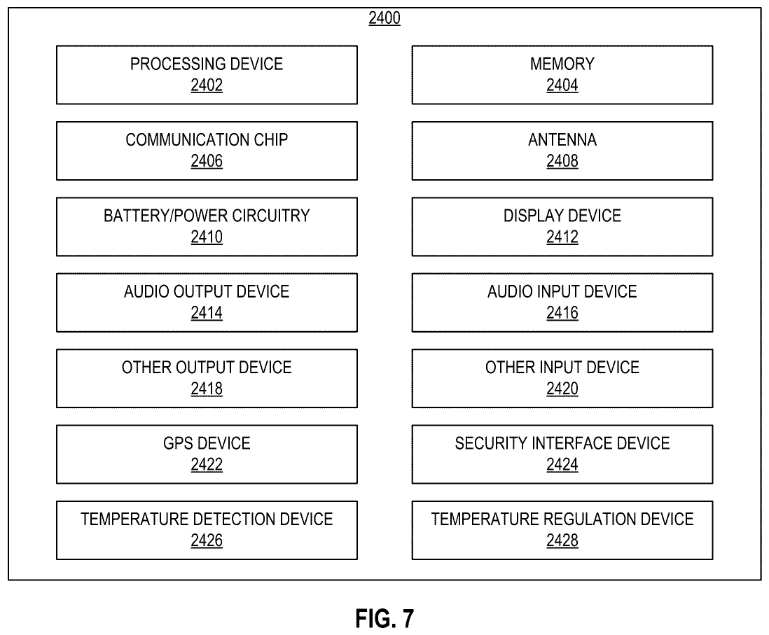

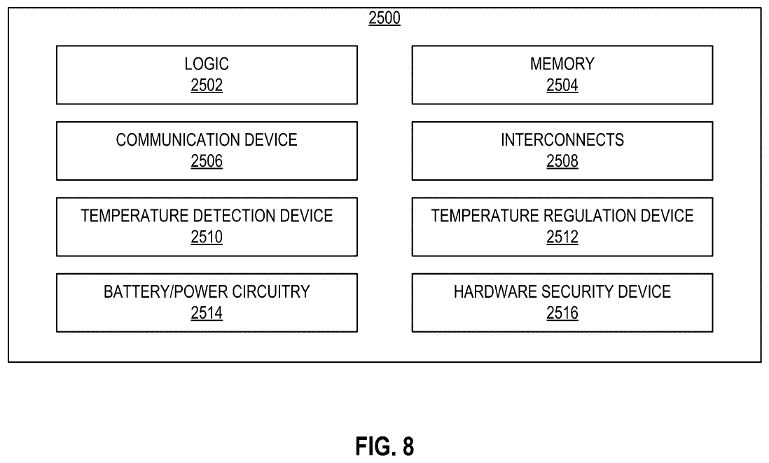

The wafer 200 may be composed of semiconductor material and may include a plurality of dies 202 having IC structures/circuits formed on/over the surface of the dies 202. Each of the dies 202 may be a repeating unit of a semiconductor product that includes any suitable IC component (e.g., in a device layer 120 of a die 202). The IC components included on any of the dies 202 may include transistors, capacitors, resistors, memory cells, transistors, capacitors, as well as any other IC components. Each of the dies 202 may also include supporting circuitry in the form of interconnect structures (e.g., conductive lines and/or conductive vias) to route signals and/or power to various IC components of the die 202 (e.g., in the plurality of the metal layers 130 associated with a given die 202). After the fabrication of the semiconductor product is complete (e.g., after manufacture of the IC structures/circuits and their supporting circuitry for routing signals and/or power), the wafer 200 may undergo a singulation process in which some of the dies 202 may be separated from all others to provide discrete “chips” or “chiplets” of an electronic component. However, as described above, in some implementations, it may be desirable to keep two or more adjacent dies 202 together (i.e., to not apply the singulation process to these dies 202). An example of that is shown in FIG. 2 with an IC device 210 that includes four dies 202, individually labeled as a die 202-1, a die 202-2, a die 202-3, and a die 202-4 (in other embodiments, the IC device 210 may include any other number of two or more adjacent, i.e., nearest neighbor, dies 202). In some embodiments, the wafer 200 or any one or more dies 202, or the IC device 210 may implement or include a memory component (e.g., one or more memory cells), a logic component (e.g., an AND, OR, NAND, or NOR gate), or any other suitable circuit element. Multiple ones of these components may be combined on a single die 202 or in a single IC device 210. For example, a memory array formed by multiple memory cells may be formed on a same die 202 or on a same IC device 210 as a processing device (e.g., the processing device 2402 of FIG. 7 or the logic 2502 of FIG. 8) or other logic that is configured to store information in the memory devices or execute instructions stored in the memory array. In some embodiments, the IC device 210 may be included in an IC package, in accordance with any of the embodiments disclosed herein. For example, the IC device 210 may be any of the IC devices 2256 in an IC package 2200 shown in FIG. 5.

The IC device 210 is an example of the IC device 100 of FIG. 1. In particular, the individual dies 202 of the IC device 210 correspond to, or may be, different areas 112 of the IC device 100, and scribe lines 214-1 and 214-2 of the IC device 210 are examples of the scribe line 114 of the IC device 100. In particular, as shown in FIG. 2, the scribe line 214-1 may define boundaries between the dies 202-1 and 202-2, as well as between the dies 202-3 and 202-4, where the width of the scribe line 214-1 may be the width 115 as described above, measured along the x-axis of the coordinate system shown, and the length of the scribe line 214-1 may be the length as described above, measured along the y-axis of the coordinate system shown. On the other hand, the scribe line 214-2 of FIG. 2 may define boundaries between the dies 202-1 and 202-3, as well as between the dies 202-2 and 202-4, where the width of the scribe line 214-2 may be the width 115 as described above, but measured along the y-axis of the coordinate system shown, and the length of the scribe line 214-2 may be the length as described above, but measured along the x-axis of the coordinate system shown.

FIG. 2 further illustrates that the IC device 210 may include a plurality of conductive lines 250 that extend over one or more scribe lines 214, shown in the example of FIG. 2 as three conductive lines 250, individually labeled as a conductive line 250-1, a conductive line 250-2, and a conductive line 250-3 (in other embodiments, the IC device 210 may include any other number of one or more conductive lines 250 that extend over one or more scribe lines 214). The scribe lines 250 may be implemented in metallization stacks of the respective dies 202 (e.g., in the metallization stacks 140), as described herein. In order to not clutter the drawing, individual details and materials of the metallization stacks and of the device layers of individual dies 202 of the IC device 210 are not illustrates, so that example positions, locations, and orientations of the conductive lines 250 may be shown. In particular, as shown in FIG. 2, a conductive line 250-1 may span across the dies 202-1 and 202-2 (e.g., may extend continuously between a metallization stack of the die 202-1 and that of the die 202-2), over the scribe line 214-1. While the conductive line 250-1 extends over a single scribe line 214, in general, any of the conductive lines 250 of the IC device 210 may extend over any number of one or more scribe lines 214. An example of that is shown in FIG. 2 with a conductive line 250-2 that spans across the dies 202-1, 202-2, and 202-3 (e.g., may extend continuously between metallization stacks of the die 202-1, 202-2, and 202-3), and is provided over the scribe line 214-1 and 214-2. Furthermore, while the conductive line 250-1 extends in a direction substantially aligned with the edges of the dies 202 (the dies 202 are typically rectangular, e.g., square, as shown in FIG. 2), in general, any of the conductive lines 250 of the IC device 210 may extend at an angle other than 0 or 90 degrees with respect to the edges of the dies 202. Examples of that are shown in FIG. 2 with the conductive line 250-2 and a conductive line 250-3, each of which is at a diagonal with respect to the edges of the dies 202. For example, in some embodiments, an angle 252, for any of the conductive lines 250, may be equal to 0 degrees or 90 degrees (depending on which edge of a rectangular die 202 the angle 252 is being measured with respect to), as is the case for the conductive line 250-1, or it may be greater than 0 degrees and less than 90 degrees, e.g., between about 5 degrees and 85 degrees, as is the case for the conductive lines 250-2 and 250-3. As shown in FIG. 2, the conductive line 250-3 may span across the dies 202-3 and 202-4 (e.g., may extend continuously between a metallization stack of the die 202-3 and that of the die 202-4), and may be provided over the scribe line 214-1. In the context of the present disclosure, a conductive line 250 may be described as extending “over” a scribe line 214 if a projection of the conductive line 250 onto a plane parallel to the support 110 (e.g., the wafer 200) that contains the scribe line 214 intersects the scribe line 214. Phrased differently, a conductive line 250 may be described as extending over a scribe line 214 if a projection of the conductive line 250 onto a plane parallel to the support 110 (e.g., the wafer 200) and a projection of the scribe line 214 onto the same plane intersect.

FIG. 2 provides one, non-limiting, example of how multiple adjacent dies 202 with corresponding scribe lines 214 between them may be included in an example IC device 210 with one or more conductive lines 250 extending over one or more scribe lines 214. Another example is shown with a wafer 200 of FIG. 3, showing another arrangement of multiple adjacent dies 202 (not individually labeled but all shown as white squares), multiple scribe lines 214 (also not individually labeled but all shown as grey lines extending between various adjacent dies 202, and a plurality of conductive lines 250 extending over various one or more of the scribe lines 214 (individually labeled in FIG. 3 as a conductive line 250-1, a conductive line 250-2, a conductive line 250-3, a conductive line 250-4, a conductive line 250-5, a conductive line 250-6, and a conductive line 250-7).

FIG. 4 illustrates a cross-sectional side view of an example IC device 400 with a conductive line extending over a scribe line, according to some embodiments of the present disclosure. The IC device 400 is an example of the IC device 100 or the IC device 210.

The IC device 400 may be formed on a substrate 410, where the substrate 410 may be any suitable support structure as described herein, e.g., the support 110 of FIG. 1 and/or the wafer 200 of FIG. 2 or FIG. 3. The substrate 410 may be part of the wafer 200 that includes two or more non-singulated die (e.g., two or more of the dies 202 of FIG. 2 or FIG. 3) included in the IC device 210 of FIG. 2 or FIG. 3. Two dies 202-1 and 202-2 are labeled in FIG. 4.

The IC device 400 may include one or more device layers 420 disposed on the substrate 410, where, together, the one or more device layers 420 may be an example of the device layer 120 of the IC device 100. Thus, the device layer 420 may include first and second portions 122-1 and 122-2, corresponding to device layers of, respectively, first and second dies 202-1 and 202-2, with the portion 124 therebetween.

As shown in FIG. 4, each of the portions 122 of the device layer 420 may include features of one or more transistors 422 (e.g., metal-oxide-semiconductor field-effect transistors (MOSFETs)) formed on the substrate 410. The device layer 420 may include, for example, one or more source and/or drain (S/D) regions 424, a gate 426 to control current flow in the transistors 422 between the S/D regions 424, and one or more S/D contacts 428 to route electrical signals to/from the S/D regions 424. The transistors 422 may include additional features not depicted for the sake of clarity, such as device isolation regions, gate contacts, and the like. The transistors 422 are not limited to the type and configuration depicted in FIG. 4 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

The S/D regions 424 may be formed within the substrate 410 adjacent to the gate 426 of each transistor 422, using any suitable processes known in the art. For example, the S/D regions 424 may be formed using either an implantation/diffusion process or a deposition process. In the former process, dopants such as boron, aluminum, antimony, phosphorous, or arsenic may be ion-implanted into the substrate 410 to form the S/D regions 424. An annealing process that activates the dopants and causes them to diffuse farther into the substrate 410 may follow the ion implantation process. In the latter process, an epitaxial deposition process may provide material that is used to fabricate the S/D regions 424. In some implementations, the S/D regions 424 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 424 may be formed using one or more alternate semiconductor materials such as germanium or a group III-V material or alloy. In further embodiments, one or more layers of metal and/or metal alloys may be used to form the S/D regions 424. In some embodiments, an etch process may be performed before the epitaxial deposition to create recesses in the substrate 410 in which the material for the S/D regions 424 is deposited.

Each transistor 422 may include a gate 426 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a P-type metal-oxide-semiconductor (PMOS) or an N-type metal-oxide-semiconductor (NMOS) transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer. For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 422 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 422 may include one layer or a stack of layers, and the one or more layers may include silicon oxide, silicon dioxide, and/or a high-k dielectric material. The high-k dielectric material included in the gate dielectric layer of the transistor 422 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

Electrical signals, such as power and/or input/output (I/O) signals, may be routed to and/or from the transistors 422 of one of the portions 122 of the device layer 420 through one or more metal layers 430 disposed above/on said portion 122 of the device layer 420, illustrated in FIG. 4 as metal layers 430-1, 430-2, 430-3, and 430-4. For each of the dies 202 of the IC device 400, a combination of the metal layers 430 forms a part of the metallization stack 140 for the die 202. For example, electrically conductive features of the device layer 420 (e.g., the gate 426 and the S/D contacts 428) may be electrically coupled with the interconnect structures 432 of the metal layers 430. Although a particular number of metal layers 430 is depicted in FIG. 4, embodiments of the present disclosure include IC devices having more or fewer metal layers than depicted. The one or more metal layers 430 may form a metallization stack 440 of the IC device 400. The metal layers 430 are examples of the metal layers 130 of the IC device 100.

The interconnect structures 432 may be arranged within the metal layers 430 to route electrical signals according to a wide variety of designs (in particular, the arrangement is not limited to the particular configuration of interconnect structures 432 depicted in FIG. 4). In some embodiments, the interconnect structures 432 may include conductive lines 432a and/or conductive vias 432b, formed of an electrically conductive material such as a metal. The conductive lines 432a may be arranged to route electrical signals in a direction of a plane that is substantially parallel with a surface of the substrate 410 upon which the device layer 420 is formed. For example, the conductive lines 432a may route electrical signals in a direction in and out of the page from the perspective of FIG. 4. The conductive vias 432b may be arranged to route electrical signals in a direction of a plane that is substantially perpendicular to the surface of the substrate 410 upon which the device layer 420 is formed. In some embodiments, the conductive vias 432b may electrically couple conductive lines 432a of different metal layers 430 together.

A first metal layer 430-1 (referred to as Metal 1 or “M1”) may be formed directly on the device layer 420. In some embodiments, the first metal layer 430-1 may include conductive lines 432a and/or conductive vias 432b, as shown. The conductive lines 432a of the first metal layer 430-1 may be coupled with contacts (e.g., the S/D contacts 428) of the device layer 420.

A second metal layer 430-2 (referred to as Metal 4 or “M2”) may be formed directly on the first metal layer 430-1. In some embodiments, the second metal layer 430-2 may include conductive vias 432b to couple the conductive lines 432a of the second metal layer 430-2 with the conductive lines 432a of the first metal layer 430-1. Although the conductive lines 432a and the conductive vias 432b are structurally delineated with a line within each metal layer (e.g., within the second metal layer 430-2) for the sake of clarity, the conductive lines 432a and the conductive vias 432b may be structurally and/or materially contiguous (e.g., simultaneously filled during a dual-damascene process) in some embodiments.

A third metal layer 430-3 (referred to as Metal 3 or “M3”) (and additional metal layers, as desired) may be formed in succession on the second metal layer 430-2 according to similar techniques and configurations described in connection with the second metal layer 430-2 or the first metal layer 430-1.

The metal layers 430 may include a dielectric material 434 disposed between the interconnect structures 432, as shown in FIG. 4. The dielectric material 434 may take the form of any of the embodiments of insulator materials disclosed herein, for example any of the embodiments discussed herein with reference to the insulating medium of the metal layers 130. In some embodiments, the dielectric material 434 disposed between the interconnect structures 432 in different ones of the metal layers 430 may have different compositions. In other embodiments, the composition of the dielectric material 434 in different metal layers 430 may be the same.

The IC device 400 may include a solder resist material 436 (e.g., polyimide or similar material) and one or more conductive contacts 438 (e.g., bond pads) formed on the metal layers 430. The conductive contacts 438 may be electrically coupled with the interconnect structures 432 and configured to route the electrical signals of the transistor(s) 422 to other external devices. For example, solder bonds may be formed on the one or more conductive contacts 438 to mechanically and/or electrically couple a chip including the IC device 400 with another component (e.g., a circuit board). The IC device 400 may have other alternative configurations to route the electrical signals from the metal layers 430 than depicted in other embodiments. For example, the conductive contacts 438 illustrated in FIG. 4 as bond pads may be replaced by or may further include other analogous features (e.g., posts) that route the electrical signals to external components.

In contrast to conventional implementations of non-singulated dies 202 where no electrical interconnect structures are provided between adjacent dies 202, the IC device 400 includes a conductive line 450 (which is an example of any of the conductive lines 250, described above) extending between one of the metal layers 430 of a metallization stack 140 of the first die 202-1 and one of the metal layers 430 of a metallization stack 140 of the second die 202-2. As shown in FIG. 4, the conductive line 450 may have a first portion electrically connected (e.g., in conductive contact) to one of the interconnect structures 432 in the metallization stack 140 of the first die 202-1 and may have a second portion electrically connected (e.g., in conductive contact) to one of the interconnect structures 432 in the metallization stack 140 of the second die 202-2. In some embodiments, the conductive line 450 may be substantially parallel to the substrate 410. In some embodiments, a critical dimension of the conductive line 450, e.g., a width of the conductive line 450 (e.g., a dimension measured along the y-axis of the coordinate system shown in FIG. 4), may be less than about 200 nanometers, e.g., less than about 100 nanometers. In some embodiments, a length of the conductive line 450 (e.g., a dimension measured along the x-axis of the coordinate system shown in FIG. 4) may be at least about 5% more than the width of the scribe line 414 between the first die 202-1 and the second die 202-2 (which may be an example of the scribe line 114, described herein), e.g., at least about 10% more or at least about 25% more. For example, in some embodiments, the length of the conductive line 450 may be at least about 210 micron, at least about 500 micron, or at least about 600 micron.

Various arrangements of the IC devices as illustrated in FIGS. 1-4 do not represent an exhaustive set of IC devices that may implement one or more conductive lines extending over one or more scribe lines as described herein, but merely provide examples of such devices/structures/assemblies. In particular, the number and positions of various elements shown in FIGS. 1-4 is purely illustrative and, in various other embodiments, other numbers of these elements, provided in other locations relative to one another may be used in accordance with the general architecture considerations described herein.

Arrangements with one or more conductive lines extending over one or more scribe lines as disclosed herein may be included in any suitable electronic device. FIGS. 5-8 illustrate various examples of devices and components that may include one or more IC devices with one or more conductive lines extending over one or more scribe lines as disclosed herein.

FIG. 5 is a side, cross-sectional view of an example IC package 2200 that may include an IC device with one or more conductive lines extending over one or more scribe lines in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the IC devices 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 5 are solder bumps, but any suitable first-level interconnects 2265 may be used. In some embodiments, no interposer 2257 may be included in the IC package 2200; instead, the IC devices 2256 may be coupled directly to the conductive contacts 2263 at the face 2272 by first-level interconnects 2265.

The IC package 2200 may include one or more IC devices 2256 coupled to the interposer 2257 via conductive contacts 2254 of the IC devices 2256, first-level interconnects 2258, and conductive contacts 2260 of the interposer 2257.

The conductive contacts 2260 may be coupled to conductive pathways (not shown) through the interposer 2257, allowing circuitry within the IC devices 2256 to electrically couple to various ones of the conductive contacts 2261 (or to other devices included in the interposer 2257, not shown). The first-level interconnects 2258 illustrated in FIG. 5 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

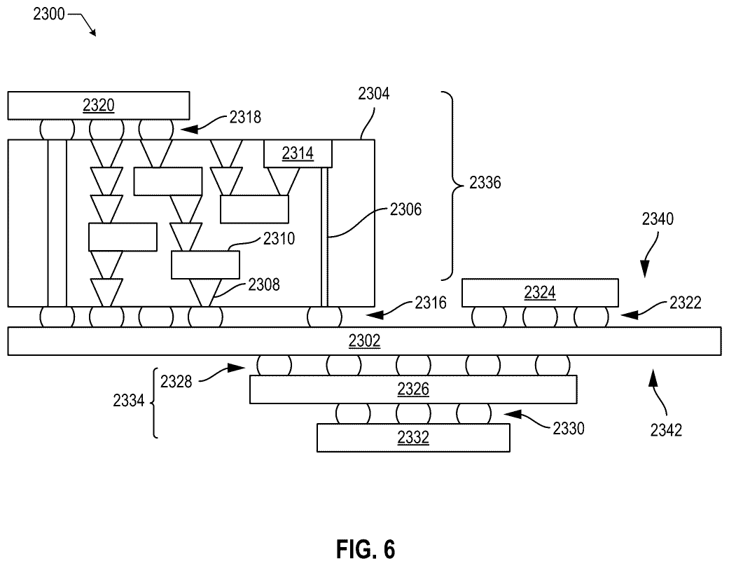

In some embodiments, an underfill material 2266 may be disposed between the package substrate 2252 and the interposer 2257 around the first-level interconnects 2265, and a mold compound 2268 may be disposed around the IC devices 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 5 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 6.

The IC devices 2256 may take the form of any of the embodiments of the IC device 100/210/400 discussed herein. In embodiments in which the IC package 2200 includes multiple IC devices 2256, the IC package 2200 may be referred to as a multi-chip package (MCP). The IC devices 2256 may include circuitry to perform any desired functionality. For example, one or more of the IC devices 2256 may include logic dies (e.g., silicon-based dies), and one or more of the IC devices 2256 may include memory dies (e.g., high bandwidth memory), including embedded memory dies. In some embodiments, any of the IC devices 2256 may include an IC device with one or more conductive lines extending over one or more scribe lines as disclosed herein, e.g., any embodiments of the IC devices 100, 210, or 400, e.g., as discussed above; in some embodiments, at least some of the IC devices 2256 may not include any conductive lines extending over one or more scribe lines. For example, in some embodiments, one of the IC devices 2256 may just be a single die, e.g., one of the dies 202

The IC package 2200 illustrated in FIG. 5 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two IC devices 2256 are illustrated in the IC package 2200 of FIG. 5, an IC package 2200 may include any desired number of the IC devices 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 6 is a cross-sectional side view of an IC device assembly 2300 that may include components having an IC device with one or more conductive lines extending over one or more scribe lines in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of an IC device with one or more conductive lines extending over one or more scribe lines in accordance with any of the embodiments disclosed herein; e.g., any of the IC packages discussed below with reference to the IC device assembly 2300 may take the form of any of the embodiments of the IC package 2200 discussed above with reference to FIG. 5 (e.g., may include an IC device with one or more conductive lines extending over one or more scribe lines provided on a IC device 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 6 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 6), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 202 of FIG. 2 or FIG. 3), an IC device, or any other suitable component. In particular, the IC package 2320 may include an IC device with one or more conductive lines extending over one or more scribe lines as described herein. Although a single IC package 2320 is shown in FIG. 6, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 6, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 6 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 7 is a block diagram of an example computing device 2400 that may include one or more components including an IC device with one or more conductive lines extending over one or more scribe lines in accordance with any of the embodiments disclosed herein. For example, any suitable ones of the components of the computing device 2400 may include a die (e.g., the die 202 of FIG. 2 or FIG. 3) having one or more conductive lines extending over one or more scribe lines as described herein. Any one or more of the components of the computing device 2400 may include, or be included in, an IC package 2200 of FIG. 5 or an IC device 2300 of FIG. 6.

A number of components are illustrated in FIG. 7 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 7, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 8 is a block diagram of an example processing device 2500 that may include an IC device with one or more conductive lines extending over one or more scribe lines in accordance with any of the embodiments disclosed herein. For example, any suitable ones of the components of the processing device 2500 may include a die (e.g., the die 202 of FIG. 2 or FIG. 3) having one or more conductive lines extending over one or more scribe lines as described herein. Any one or more of the components of the processing device 2500 may include, or be included in, an IC device 2300 (FIG. 6). Any one or more of the components of the processing device 2500 may include, or be included in, an IC package 2200 of FIG. 5 or an IC device 2300 of FIG. 6. Any one or more of the components of the processing device 2500 may include, or be included in, a computing device 2400 of FIG. 7; for example, the processing device 2500 may be the processing device 2402 of the computing device 2400.

A number of components are illustrated in FIG. 8 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 8, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 7). In some embodiments, the memory 2504 may be a designated device configured to provide storage functionality for the components of the processing device 2500 (e.g., local), while the memory 1604 may be configured to provide system-level storage functionality for the entire computing device 2400 (e.g., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, e.g., the size and capabilities of each component. With hierarchical memory, each of the various memory components can be viewed as part of a hierarchy of memories (m₁, m₂, . . . , mₙ) in which each member m; is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 7). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, MIM structures, etc.

The processing device 2500 may include a temperature detection device 2510 which may be implemented substantially as described above with reference to the temperature detection device 2426 of FIG. 7 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 7 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 7. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 7. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide various examples of the embodiments disclosed herein.

Example 1 provides an IC device that includes a substrate including a plurality of areas and one or more scribe lines defining boundaries of individual areas of the plurality of areas, where the plurality of areas includes a first area and a second area adjacent to the first area, and where the one or more scribe lines include a scribe line between the first area and the second area; a first device layer over the first area of the substrate; a first metallization stack over the first device layer; a second device layer over the second area of the substrate; a second metallization stack over the second device layer; and a conductive line extending (e.g., being materially and electrically continuous) between the first metallization stack and the second metallization stack, where a projection of the conductive line onto a plane parallel to the substrate and containing the scribe line intersects the scribe line.

Example 2 provides the IC device according to example 1, where a portion of the conductive line in the first metallization stack is in a first metal layer of the first metallization stack, the conductive line is a first conductive line, and the first metallization stack further includes a second conductive line in a second metal layer of the first metallization stack, where the second metal layer is either closer to the substrate than the first metal layer (i.e., the second conductive line is in a metal layer below the metal layer with the conductive line that extends to the second metallization stack) or further away from the substrate than the first metal layer (i.e., the second conductive line is in a metal layer above the metal layer with the conductive line that extends to the second metallization stack).

Example 3 provides the IC device according to example 2, where an angle between a projection of the second conductive line onto the plane and a projection of the first conductive line onto the plane is between 5 degrees and 85 degrees.

Example 4 provides the IC device according to examples 2 or 3, where the first metallization stack further includes a third conductive line in a third metal layer of the first metallization stack, where the first metal layer is between the second metal layer and the third metal layer (i.e., the conductive line that extends to the second metallization stack is sandwiched between two other metal layers of the first metallization stack).

Example 5 provides the IC device according to example 4, where a portion of the conductive line in the second metallization stack is in a first metal layer of the second metallization stack, and the second metallization stack further includes a fourth conductive line in a second metal layer of the second metallization stack, where the second metal layer of the second metallization stack is either closer to the substrate than the first metal layer of the second metallization stack (i.e., the fourth conductive line is in a metal layer below the metal layer with the conductive line that extends to the first metallization stack) or further away from the substrate than the first metal layer of the second metallization stack (i.e., the fourth conductive line is in a metal layer above the metal layer with the conductive line that extends to the first metallization stack).

Example 6 provides the IC device according to example 5, where an angle between a projection of the fourth conductive line onto the plane and a projection of the first conductive line onto the plane is between 5 degrees and 85 degrees.

Example 7 provides the IC device according to examples 5 or 6, where the second metallization stack further includes a fifth conductive line in a third metal layer of the second metallization stack, where the first metal layer of the second metallization stack is between the second metal layer of the second metallization stack and the third metal layer of the second metallization stack (i.e., the conductive line that extends to the first metallization stack is sandwiched between two other metal layers of the second metallization stack).

Example 8 provides the IC device according to any one of the preceding examples, where the first device layer and the second device layer include a plurality of transistors and are portions of a device layer of the IC device, and where no transistors connected to any of the plurality of transistors are present in a portion of the device layer above the scribe line.

Example 9 provides the IC device according to any one of the preceding examples, where a critical dimension of the conductive line is less than about 100 nanometers.

Example 10 provides the IC device according to example 9, where the critical dimension is a width of the conductive line.

Example 11 provides the IC device according to any one of the preceding examples, where a length of the conductive line is at least about 600 micron.

Example 12 provides the IC device according to any one of the preceding examples, where the conductive line is substantially parallel to the substrate.

Example 13 provides the IC device according to any one of the preceding examples, where a width of the scribe line is between about 50 micron and 200 micron.

Example 14 provides the IC device according to any one of the preceding examples, where a length of the scribe line is at least about 1 millimeter.

Example 15 provides an IC device, including: a support (e.g., a portion of a wafer) including a first area, a second area, and a division line between the first area and the second area; a device layer over the support, the device layer including a first portion over the first area, a second portion over the second area, and a third portion over the division line; a metallization stack over the device layer, the metallization stack including the first portion of the device layer, a second portion over the second portion of the device layer, and a third portion over the third portion of the device layer; a conductive line having a first portion in the first portion of the metallization stack, a second portion in the second portion of the metallization stack, and a third portion in the third portion of the metallization stack, where the first, second, and third portions of the conductive line are materially and electrically continuous portions of the conductive line, and a width of the division line is between about 50 micron and 200 micron.

Example 16 provides the IC device according to example 15, where the first portion of the device layer includes a first plurality of IC components, the second portion of the device layer include a second plurality of IC components, where the conductive line electrically connects at least one IC component of the first plurality of the IC components and at least one IC component of the second plurality of the IC components, and where all IC components in the third portion of the device layer are electrically disconnected from all IC components of the first plurality of IC components and all IC components of the second plurality of IC components.

Example 17 provides the IC device according to examples 15 or 16, where the conductive line is a first conductive line, the IC device further includes a second conductive line in the first portion of the metallization stack (e.g., limited to the first portion of the metallization stack, i.e., not extending to the third or second portions of the metallization stack), and an angle between a projection of the second conductive line onto a plane parallel to the support and a projection of the first conductive line onto the plane is between 5 degrees and 85 degrees.

Example 18 provides the IC device according to example 17, further including a plurality of further conductive lines in the first portion of the metallization stack (e.g., limited to the first portion of the metallization stack, i.e., not extending to the third or second portions of the metallization stack), projections of the further conductive lines onto the plane are parallel to one another, and an angle between one of the projections of the further conductive lines and the projection of the first conductive line onto the plane is between 5 degrees and 85 degrees.

Example 19 provides an IC package that includes an IC device and a further component, coupled to the IC device, where the IC device is an IC device according to any one of the preceding examples. For example, the IC device includes a substrate including a first area, a second area, and a scribe line between the first area and the second area; a first device layer over the first area of the substrate, and a first metallization stack over the first device layer; a second device layer over the second area of the substrate, and a second metallization stack over the second device layer; and a conductive line extending (e.g., being materially and electrically continuous) between the first metallization stack and the second metallization stack, where a projection of the conductive line onto a plane parallel to the substrate and containing the scribe line intersects the scribe line.

Example 20 provides the IC package according to example 19, where the further component is or includes one of a package substrate, an interposer, or an IC die.

In various further examples of the IC package according to examples 19 or 20, the further component may be coupled to the IC die via one or more first-level interconnects, where the one or more first-level interconnects may include one or more solder bumps, solder posts, or bond wires.

In further examples of the IC package according to any of the preceding examples, the IC die includes, or is a part of, at least one of a memory device, a computing device, a wearable device, a handheld electronic device, and a wireless communications device.

Example 21 provides an electronic device that includes a carrier substrate; and one or more of the IC device according to any one of the preceding examples and the IC package according to any one of the preceding examples, coupled to the carrier substrate.

Example 22 provides the electronic device according to example 21, where the carrier substrate is a motherboard.

Example 23 provides the electronic device according to example 21, where the carrier substrate is a PCB.

Example 24 provides the electronic device according to any one of examples 21-23, where the electronic device is a wearable electronic device (e.g., a smart watch) or handheld electronic device (e.g., a mobile phone).

Example 25 provides the electronic device according to any one of examples 21-24, where the electronic device further includes one or more communication chips and an antenna.

Example 26 provides the electronic device according to any one of examples 21-25, where the electronic device is a memory device.

Example 27 provides the electronic device according to any one of examples 21-25, where the electronic device is one of an RF transceiver, a switch, a power amplifier, a low-noise amplifier, a filter, a filter bank, a duplexer, an upconverter, or a downconverter of an RF communications device, e.g., of an RF transceiver.

Example 28 provides the electronic device according to any one of examples 21-25, where the electronic device is a computing device.

Example 29 provides the electronic device according to any one of examples 21-28, where the electronic device is included in a base station of a wireless communication system.

Example 30 provides the electronic device according to any one of examples 21-28, where the electronic device is included in a user equipment device (i.e., a mobile device) of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a substrate comprising a plurality of areas and one or more scribe lines defining boundaries of individual areas of the plurality of areas, wherein the plurality of areas includes a first area and a second area adjacent to the first area, and wherein the one or more scribe lines include a scribe line between the first area and the second area;
a first device layer over the first area of the substrate;
a first metallization stack over the first device layer;
a second device layer over the second area of the substrate;
a second metallization stack over the second device layer; and
a conductive line extending between the first metallization stack and the second metallization stack, wherein a projection of the conductive line onto a plane parallel to the substrate and containing the scribe line intersects the scribe line.

2. The IC device according to claim 1, wherein:
a portion of the conductive line in the first metallization stack is in a first metal layer of the first metallization stack,
the conductive line is a first conductive line, and
the first metallization stack further includes a second conductive line in a second metal layer of the first metallization stack, wherein the second metal layer is either closer to the substrate than the first metal layer or further away from the substrate than the first metal layer.

3. The IC device according to claim 2, wherein an angle between a projection of the second conductive line onto the plane and a projection of the first conductive line onto the plane is between 5 degrees and 85 degrees.

4. The IC device according to claim 2, wherein:
the first metallization stack further includes a third conductive line in a third metal layer of the first metallization stack, wherein the first metal layer is between the second metal layer and the third metal layer.

5. The IC device according to claim 4, wherein:
a portion of the conductive line in the second metallization stack is in a first metal layer of the second metallization stack, and
the second metallization stack further includes a fourth conductive line in a second metal layer of the second metallization stack, wherein the second metal layer of the second metallization stack is either closer to the substrate than the first metal layer of the second metallization stack or further away from the substrate than the first metal layer of the second metallization stack.

6. The IC device according to claim 5, wherein an angle between a projection of the fourth conductive line onto the plane and a projection of the first conductive line onto the plane is between 5 degrees and 85 degrees.

7. The IC device according to claim 5, wherein:
the second metallization stack further includes a fifth conductive line in a third metal layer of the second metallization stack, wherein the first metal layer of the second metallization stack is between the second metal layer of the second metallization stack and the third metal layer of the second metallization stack.

8. The IC device according to claim 1, wherein the first device layer and the second device layer include a plurality of transistors and are portions of a device layer of the IC device, and wherein no transistors connected to any of the plurality of transistors are present in a portion of the device layer above the scribe line.

9. The IC device according to claim 1, wherein a critical dimension of the conductive line is less than about 100 nanometers.

10. The IC device according to claim 9, wherein the critical dimension is a width of the conductive line.

11. The IC device according to claim 1, wherein a length of the conductive line is at least about 600 micron.

12. The IC device according to claim 1, wherein the conductive line is substantially parallel to the substrate.

13. The IC device according to claim 1, wherein a width of the scribe line is between about 50 micron and 200 micron.

14. The IC device according to claim 1, wherein a length of the scribe line is at least about 1 millimeter.

15. An integrated circuit (IC) device, comprising:
a support comprising a first area, a second area, and a division line between the first area and the second area;
a device layer over the support, the device layer comprising a first portion over the first area, a second portion over the second area, and a third portion over the division line;
a metallization stack over the device layer, the metallization stack comprising the first portion of the device layer, a second portion over the second portion of the device layer, and a third portion over the third portion of the device layer;
a conductive line having a first portion in the first portion of the metallization stack, a second portion in the second portion of the metallization stack, and a third portion in the third portion of the metallization stack, wherein the first, second, and third portions of the conductive line are materially and electrically continuous portions of the conductive line, and wherein a width of the division line is between about 50 micron and 200 micron.

16. The IC device according to claim 15, wherein the first portion of the device layer includes a first plurality of IC components, the second portion of the device layer include a second plurality of IC components, wherein the conductive line is coupled to at least one IC component of the first plurality of the IC components and at least one IC component of the second plurality of the IC components, and wherein all IC components in the third portion of the device layer are electrically isolated from all IC components of the first plurality of IC components and all IC components of the second plurality of IC components.

17. The IC device according to claim 15, wherein the conductive line is a first conductive line, the IC device further includes a second conductive line in the first portion of the metallization stack, and an angle between a projection of the second conductive line onto a plane parallel to the support and a projection of the first conductive line onto the plane is between 5 degrees and 85 degrees.

18. The IC device according to claim 17, further comprising a plurality of further conductive lines in the first portion of the metallization stack, projections of the further conductive lines onto the plane are parallel to one another, and an angle between one of the projections of the further conductive lines and the projection of the first conductive line onto the plane is between 5 degrees and 85 degrees.

19. An integrated circuit (IC) package, comprising:
an IC device; and
a further component, coupled to the IC device,
wherein the IC device includes:
a substrate comprising a first area, a second area, and a scribe line between the first area and the second area,
a first device layer over the first area of the substrate, and a first metallization stack over the first device layer,
a second device layer over the second area of the substrate, and a second metallization stack over the second device layer, and
a conductive line extending between the first metallization stack and the second metallization stack, wherein a projection of the conductive line onto a plane parallel to the substrate and containing the scribe line intersects the scribe line.

20. The IC package according to claim 19, wherein the further component is one of a package substrate, an interposer, or an IC die.
